(19) United States
(12) Patent Application Publication
(10) Pub. No.: US 2025/0130504 A1
(43) Pub. Date: Apr. 24, 2025

(54) OPTICAL ELEMENT AND PROJECTION EXPOSURE APPARATUS FOR SEMICONDUCTOR LITHOGRAPHY

(71) Applicant: Carl Zeiss SMT GmbH, Oberkochen (DE)

(72) Inventors: Dieter Bader, Goeggingen (DE); Matthias Manger, Aalen (DE); Markus Raab, Schillingsfuerst (DE); Andreas Raba, Niederschoenenfeld (DE)

(21) Appl. No.: 19/005,199

(22) Filed: Dec. 30, 2024

Related U.S. Application Data
(63) Continuation of application No. PCT/EP2023/063765, filed on May 23, 2023.

(30) Foreign Application Priority Data
Jul. 5, 2022 (DE) 10 2022 116 699.6

(51) Int. Cl. G03F 7/00

(52) U.S. Cl. CPC G03F 7/70266

(57) ABSTRACT

An optical element for a projection exposure apparatus for semiconductor lithography comprises a main body and at least two actuators connected to the main body. The actuators are designed for deforming an optical effective surface of the optical element. The at least two actuators are ring actuators. A corresponding apparatus comprises such an optical element.

### CROSS-REFERENCE TO RELATED APPLICATIONS

The present application is a continuation of, and claims benefit under 35 USC 120 to, international application No. PCT/EP2023/063765, filed May 23, 2023, which claims benefit under 35 USC 119 of German Application No. 10 2022 116 699.6, filed Jul. 5, 2022. The entire disclosure of each of these applications is incorporated by reference herein.

### FIELD

The disclosure relates to an optical element for a projection exposure apparatus for semiconductor lithography, and to a projection exposure apparatus for semiconductor lithography equipped with a corresponding optical element.

### BACKGROUND

In projection exposure apparatuses of this type, microscopically small structures are imaged, starting from a mask as the template, onto a wafer coated with photoresist at a greatly reduced size using photolithographic methods. In subsequent development and further processing steps, the desired structures, for instance memory or logic elements, are created on the wafer, which is then divided into individual chips for use in electronic equipment.

Owing to the very small structures to be created down to the nanometer range, the optical units of the projection exposure apparatuses, and thus the optical elements used, are typically subjected to extreme demands. Moreover, imaging aberrations that often stem from changing ambient conditions, such as temperature changes in the optical unit, regularly occur during the operation of a corresponding apparatus.

This is typically addressed by the optical elements used, such as lens elements or mirrors, being designed to be movable or deformable in order to enable the correction of the aforementioned imaging aberrations during the operation of the apparatus. For this purpose, use is generally made of mechanical actuators which may be suitable, for example, for deforming the surface of an optical element used for imaging, i.e. the so-called optical effective surface, in a targeted manner. This deformation can be carried out from the rear side of a main body of the corresponding optical element.

A regular challenge for the arrangement of the actuators on the rear side of the main body is to create a reliable mechanical connection between actuator and main body, wherein simple producibility and a relatively small undesirable influence of the connection technique on the optical performance of the corresponding optical element are available.

### SUMMARY

The present disclosure seeks to provide an optical element and a projection exposure apparatus for semiconductor lithography in which a simplified arrangement of actuators for mechanically manipulating optical elements is implemented.

An optical element according to the disclosure for a projection exposure apparatus for semiconductor lithography comprises a main body and at least one actuator connected to the main body, the actuator being configured as a ring actuator. In this case, the ring actuator can be connected to the main body via a linking geometry. The actuator can be configured as a solid-state actuator, for example as a piezoactuator or an electrostrictive actuator. It can serve in this case for deforming the main body and thus also for deforming the optical effective surface in order to produce a desired surface profile of the optical effective surface for achieving a corresponding optical effect. The optical element can be a multilayer mirror in a projection exposure apparatus for semiconductor lithography. In this case, a ring actuator should be understood to mean a ring-shaped actuator, which can have a substantially hollow-cylindrical basic shape. This choice of the geometry of the actuator can afford enhanced integrability or possibility of connection of the actuator with/to the main body.

In this regard, for example, the linking geometry can be configured as a pin arranged on the main body, and the ring actuator can be simply pushed onto the pin.

The main body and the pin can be configured in a monolithic fashion, i.e. in an integral fashion, but it is likewise conceivable for the main body and the pin to be connected to one another in an integrally bonded manner. Furthermore, interlocking engagement and force-locking engagement are also conceivable.

In one variant of the disclosure, the linking geometry can be configured as a cutout arranged in the main body, the cutout being adapted to the external geometry of the ring actuator.

The contact area of the ring actuator with respect to the linking geometry of the main body can be configured in a conical fashion, and likewise the contact area of the linking geometry of the main body with respect to the ring actuator can also be configured in a conical fashion. This measure can help simplify the mounting of the actuator on or in the linking geometry. The mounting itself can be effected by thermal shrink fitting thereon or shrink fitting therein; other mounting techniques are also conceivable, such as for example a pre-deflection of the actuator by applying a voltage.

A certain fit can be realized by way of an axial displacement. This can open up the possibility of enabling a frictional engagement and thus a fixing of the ring actuator on the pin or in the cutout by way of a pressing, for example. The measures described make it possible, in principle, to connect the ring actuator without the use of an adhesive, but that does not exclude the use of an additional integrally bonded connection.

The actuator effect can be enhanced by virtue of the linking geometry of the ring actuator comprising a suitably designed mechanical transmission region. For example, in this case, the transmission region can be configured in such a way that it reduces a stiffness acting against the deflection of the ring actuator, with the result that the force to be applied on the part of the actuator can remain moderate.

In one embodiment of the disclosure, the ring actuator is arranged between the main body and a supporting structure. In this case, the supporting structure can comprise a linking geometry corresponding to the ring actuator, thereby affording a simple possibility of connection of the actuator to the supporting structure.

The ring actuators can be connected to a linking geometry configured as pins or cutouts in the main body and in the supporting structure.

By virtue of the rear support of the ring actuators, both expansions of the actuator can contribute to the deformation of the optical effective surface.

Moreover, there are various possibilities for fixing the main body and the supporting structure. In this regard, the main body can be connected to the fixed world, and the supporting structure can be connected to the main body merely via the actuators. It is likewise conceivable for the supporting structure to be connected to the fixed world, and for the main body to be held via the actuators. It is also conceivable for the main body and supporting structure to be connected to one another.

In the case where the main body is mounted via the actuators, it is conceivable to achieve a translational displacement of the main body by way of all the actuators being controlled simultaneously and in the same way; however, the associated transverse contraction of the actuators can potentially lead to parasitic effects. Such effects could however be reduced by a one-off or regular calibration.

In a variant of the disclosure, the ring actuator is integrated into the supporting structure. In this regard, for example, the entire supporting structure can be fabricated from a piezoelectric material and the actuators can be realized by the integration of a suitable electrode geometry into the supporting structure.

Optionally, actuation directions of the ring actuators can be defined by virtue of the electrodes and the actuator material of the ring actuators being aligned radially or axially in layers.

For the present disclosure, but also generally, it can be desirable for an optical element to comprise a sensor for determining the deformation of an optical effective surface of the optical element, wherein the sensor is designed to detect a signal which permits a correlation with the deformation of the optical effective surface. In this case, the deformation of the optical effective surface need not necessarily be measured directly. It can be sufficient to record a signal from which the deformation of the optical effective surface can be deduced.

In order to obtain such a signal, it can be desirable for the sensor to comprise an interferometer, such as a Fabry-Perot interferometer. Interferometers can combine the possibilities of extremely accurate and at the same time non-contact measurements. In this case, it can be desirable for both the main body and the linking geometry to comprise comparatively precisely fabricated optical surfaces which can be used as reflection surfaces for the interferometer.

The measurement technique described can be suitable, in principle, for a wide variety of optical elements, such as optical elements as described in the present application; the optical element can thus be a deformable mirror, for example.

In this case, the deformable mirror can be a force-actuated mirror.

The deformable mirror can be a mirror actuated by a solid-state actuator.

An actuation direction of the actuator can be aligned normal to a contact area of the actuator with the optical element; additionally or alternatively, an actuation direction of the actuator can also be aligned parallel to a contact area of the actuator with the optical element.

In the case where ring actuators are used, the geometry of such actuators can be utilized to the effect that the sensor detects the deformation of the optical effective surface through the center of a ring actuator. This can allow measurement to take place comparatively near the region of interest.

In principle, the disclosure can be realized for example using piezoactuators which can act bidirectionally, i.e. also change their respective expansion direction when the polarity of the control signal changes. Piezoactuators composed of monocrystalline lithium niobate (LiNbO₃) can be suitable for such applications, for example.

### BRIEF DESCRIPTION OF THE DRAWINGS

Exemplary embodiments and variants of the disclosure are explained in greater detail below with reference to the drawing, in which:

FIG. 1 schematically shows a meridional section through a projection exposure apparatus for EUV projection lithography,

FIG. 2 schematically shows a meridional section through a projection exposure apparatus for DUV projection lithography,

FIG. 3 shows a ring actuator in three different operating states for elucidating the functioning,

FIGS. 4A-4B show embodiments concerning the construction of a ring actuator,

FIGS. 5A-5C show embodiments of an optical element according to the disclosure,

FIGS. 6A-6B show a schematic illustration of the disclosure for elucidating the mode of action,

FIGS. 7A-7B show one embodiment of the disclosure using a pin,

FIGS. 8A-8B show one embodiment of the disclosure using a cutout,

FIGS. 9A-9B show one embodiment of the disclosure with a mechanical transmission region,

FIGS. 10A-10B show a further embodiment of the disclosure with a mechanical transmission region,

FIGS. 11A-11B show one embodiment of the disclosure with a supporting structure,

FIG. 12 shows one embodiment of the disclosure with an integrated actuator system,

FIGS. 13A-13B show one embodiment of the disclosure using a sensor, and

FIG. 14 shows a schematic illustration concerning the control of a ring actuator for mounting purposes.

### DETAILED DESCRIPTION

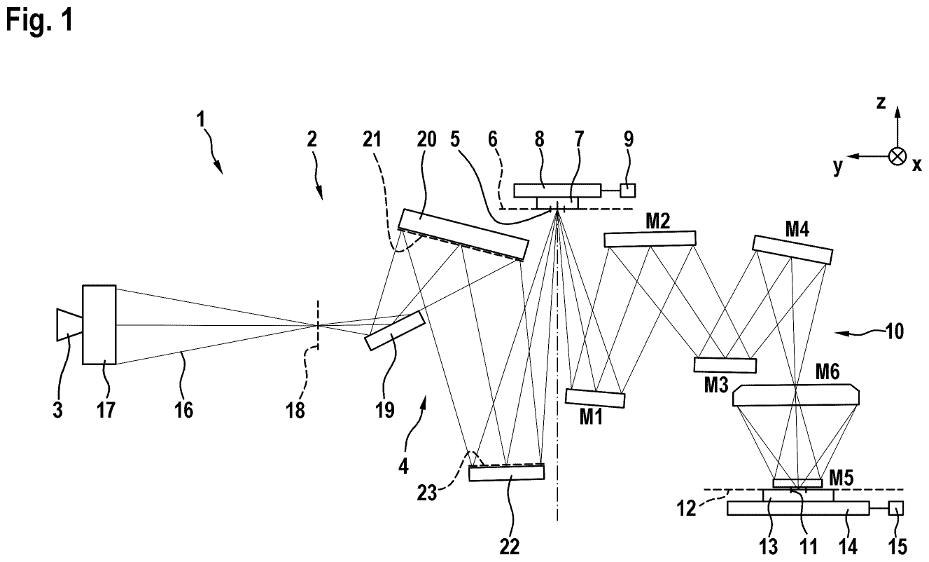

Certain constituent parts of a microlithographic projection exposure apparatus 1 are described in exemplary fashion below, initially with reference to FIG. 1. The description of the fundamental construction of the projection exposure apparatus 1 and the constituent parts thereof is understood here to be non-limiting.

One embodiment of an illumination system 2 of the projection exposure apparatus 1 has, in addition to a radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable by way of a reticle displacement drive 9, for example in a scanning direction.

For explanation purposes, a Cartesian xyz-coordinate system is depicted in FIG. 1. The x-direction runs perpendicularly to the plane of the drawing into the latter. The y-direction runs horizontally, and the z-direction runs vertically. The scanning direction runs along the y-direction in FIG. 1. The z-direction runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, such as along the y-direction. The displacement, firstly, of the reticle 7 by way of the reticle displacement drive 9 and, secondly, of the wafer 13 by way of the wafer displacement drive 15 can be implemented so as to be synchronized with one another.

The radiation source 3 is an EUV radiation source. The radiation source 3 emits EUV radiation 16, which is also referred to below as used radiation, illumination radiation or illumination light. The used radiation can have a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 can be a free electron laser (FEL).

The illumination radiation 16 emanating from the radiation source 3 is focused by a collector 17. The collector 17 can be a collector with one or with a plurality of ellipsoidal and/or hyperboloidal reflection surfaces. The illumination radiation 16 can be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 can be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 can constitute a separation between a radiation source module, comprising the radiation source 3 and the collector 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the purely deflecting effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 which is optically conjugate to the object plane 6 as a field plane, then this facet mirror is also referred to as a field facet mirror. The first facet mirror 20 comprises a multiplicity of individual first facets 21, which are also referred to below as field facets. FIG. 1 illustrates only some of the facets 21 by way of example.

The first facets 21 can be embodied as macroscopic facets, such as rectangular facets or as facets with an arcuate edge contour or an edge contour of part of a circle. The first facets 21 can be embodied as plane facets or alternatively as convexly or concavely curved facets.

As known for example from DE 10 2008 009 600 A1, the first facets 21 themselves can also be composed in each case of a multiplicity of individual mirrors, such as a multiplicity of micromirrors. The first facet mirror 20 can be configured as a microelectromechanical system (MEMS system). For details, reference is made to DE 10 2008 009 600 A1.

Between the collector 17 and the deflection mirror 19, the illumination radiation 16 travels horizontally, i.e. along the y-direction.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or alternatively be facets composed of micromirrors. In this regard, reference is likewise made to DE 10 2008 009 600 A1.

The second facets 23 can have plane reflection surfaces or, alternatively, convexly or concavely curved reflection surfaces.

The illumination optical unit 4 consequently forms a doubly faceted system. This fundamental principle is also referred to as a fly's eye condenser (fly's eye integrator).

It can be desirable to arrange the second facet mirror 22 not exactly in a plane that is optically conjugate to a pupil plane of the projection optical unit 10. The pupil facet mirror 22 can be arranged so as to be tilted relative to a pupil plane of the projection optical unit 10, as is described, for example, in DE 10 2017 220 586 A1.

With the aid of the second facet mirror 22, the individual first facets 21 are imaged into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing to the imaging of the first facets 21 into the object field 5 can be arranged in the beam path between the second facet mirror 22 and the object field 5. The transfer optical unit can have exactly one mirror or, alternatively, two or more mirrors, which are arranged in succession in the beam path of the illumination optical unit 4. The transfer optical unit can comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20, and the pupil facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection optical unit 10 is a doubly obscured optical unit. The projection optical unit 10 has an image-side numerical aperture which is greater than 0.5 and which can also be greater than 0.6 and, for example, can be 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, such as with alternating layers of molybdenum and silicon.

The projection optical unit 10 has a large object-image offset in the y-direction between a y-coordinate of a center of the object field 5 and a y-coordinate of the center of the image field 11. This object-image offset in the y-direction can be of approximately the same magnitude as a z-distance between the object plane 6 and the image plane 12.

The projection optical unit 10 can have an anamorphic configuration. It can have different imaging scales βx, βy in the x-and y-directions. The two imaging scales βx, βy of the projection optical unit 10 can be (βx, βy)=(+/−0.25,+/−0.125). A positive imaging scale β means imaging without image inversion. A negative sign for the imaging scale β means imaging with image inversion.

The projection optical unit 10 consequently leads to a reduction in size with a ratio of 4:1 in the x-direction, i.e. in a direction perpendicular to the scanning direction.

The projection optical unit 10 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 5 and the image field 11 can be the same or can be different depending on the design of the projection optical unit 10. Examples of projection optical units with different numbers of such intermediate images in the x- and y-directions are known from US 2018/0074303 A1.

In each case, one of the pupil facets 23 is assigned to exactly one of the field facets 21 for the purpose of forming a respective illumination channel for illuminating the object field 5. This can produce illumination according to the Köhler principle. The far field is decomposed into a multiplicity of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 can be as homogeneous as possible. It can have a uniformity error of less than 2%. Field uniformity can be achieved by overlaying different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, for example the subset of the pupil facets which guide light. This intensity distribution is also referred to as illumination setting.

A likewise preferred pupil uniformity in the region of portions of an illumination pupil of the illumination optical unit 4 which are illuminated in a defined manner can be achieved by a redistribution of the illumination channels.

Further aspects and details of the illumination of the object field 5 and of the entrance pupil of the projection optical unit 10 are described below.

The projection optical unit 10 can have a homocentric entrance pupil. The latter can be accessible. It can also be inaccessible.

The entrance pupil of the projection optical unit 10 regularly cannot be exactly illuminated using the pupil facet mirror 22. In the case of imaging of the projection optical unit 10 which telecentrically images the center of the pupil facet mirror 22 onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. This area can exhibit a finite curvature.

It may be the case that the projection optical unit 10 has different positions of the entrance pupil for the tangential beam path and for the sagittal beam path. In this case, an imaging element, such as an optical component of the transfer optical unit, should be provided between the second facet mirror 22 and the reticle 7. With the aid of this optical element, the different positions of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

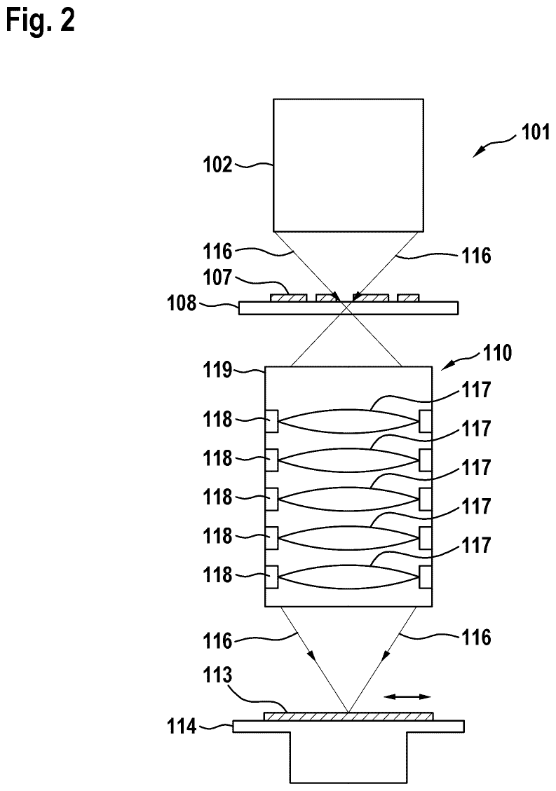

FIG. 2 schematically shows a meridional section through a further projection exposure apparatus 101 for DUV projection lithography, in which the disclosure can likewise be used.

The setup of the projection exposure apparatus 101 and the principle of the imaging are comparable with the setup and procedure described in FIG. 1. Identical components are denoted by a reference sign increased by 100 with respect to FIG. 1, i.e. the reference signs in FIG. 2 start at 101.

In contrast to an EUV projection exposure apparatus 1 as described in FIG. 1, refractive, diffractive and/or reflective optical elements 117, such as for example lens elements, mirrors, prisms, terminating plates, and the like, can be used for imaging or for illumination in the DUV projection exposure apparatus 101 on account of the greater wavelength of the DUV radiation 116, employed as used light, in the range from 100 nm to 300 nm, such as of 193 nm. The projection exposure apparatus 101 in this case comprises an illumination system 102, a reticle holder 108 for receiving and exactly positioning a reticle 107 provided with a structure, the reticle determining the later structures on a wafer 113, a wafer holder 114 for holding, moving, and exactly positioning this very wafer 113, and a projection lens 110, with a plurality of optical elements 117 held by way of mounts 118 in a lens housing 119 of the projection lens 110.

The illumination system 102 provides DUV radiation 116 for imaging the reticle 107 on the wafer 113. A laser, a plasma source or the like can be used as the source of this radiation 116. The radiation 116 is shaped in the illumination system 102 via optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the setup of the downstream projection optical unit 110 with the lens housing 119 does not differ in principle from the setup described in FIG. 1 and is therefore not described in further detail.

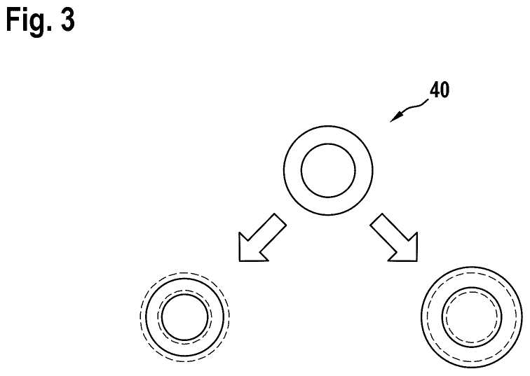

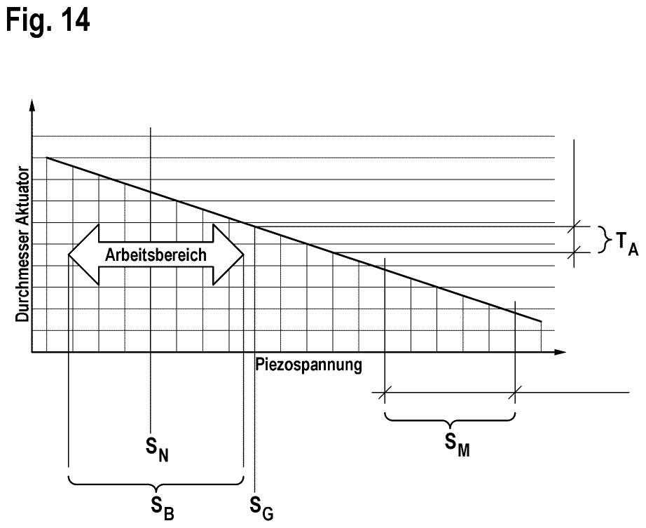

FIG. 3 shows a schematic illustration of a ring actuator 40 in three different operating states. At the top in FIG. 3, the ring actuator 40 having a hollow-cylindrical recess is illustrated in a zero state, defined by half of the possible total deflection in the example shown. From this zero state, the ring actuator 40 can expand, as is illustrated at the bottom on the left-hand side in FIG. 3, or contract, as illustrated at the bottom on the right-hand side. As will be explained in greater detail further below in FIG. 14 in connection with the mounting and operation of the ring actuator 40, the zero state is caused in the case of a specific zero voltage in the zero state and the expansion and contraction of the ring actuator 40 are caused by an increase or decrease in the voltage by way of a controller (not illustrated). Alternatively, if a suitable material is used, the zero state can also correspond to the voltage-free state. In this case, expansion is caused by applying a voltage having a first polarity, and contraction by applying a voltage having an opposite polarity. Suitable materials for this are for example ceramic materials, for example lead zirconate titanate (PZT), furthermore for example lithium niobate (LiNbO₃) or lithium tantalate (LiTaO₃).

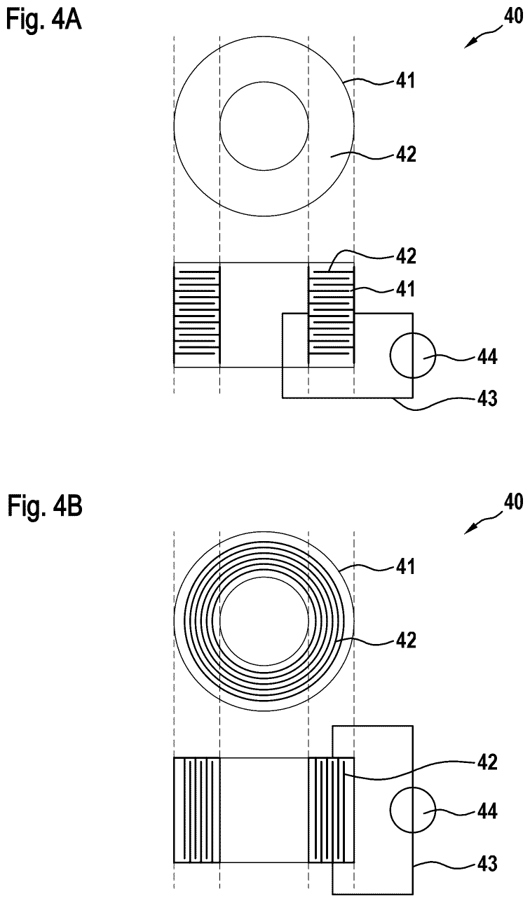

FIG. 4A and FIG. 4B show two different embodiments of a ring actuator 40, which differ in the arrangement of the electrodes 42 and the actuator material 41 in relation to the longitudinal axis of the ring actuator 40.

FIG. 4A shows an axial setup—known in the case of rod actuators from the prior art—of layers of actuator material 41 and electrodes 42, which are connected to a controller 44 via lines 43. In the embodiment shown in FIG. 4A, the electrodes 42 are arranged first of all on the inner side of the ring actuator 40 and then on the outer side of the ring actuator 40, it also being possible for both electrodes 42 to be contacted only on the outer side or only on the inner side. The arrangement of the electrodes 42 can cause for example a primary deflection of the ring actuator 40 in an axial direction, i.e. perpendicular to the ring plane, the expansion and contraction of the ring actuator 40 in a radial direction being merely a second-order effect.

FIG. 4B shows a radial setup of the ring actuator 40, in which the layers of actuator material 41 and electrodes 42 are configured radially. In this case, contact is made with a controller 44 via lines 43 at the upper and lower end faces of the ring actuator 40. As already explained in the case of FIG. 4A, an arrangement of the contacting of the lines 43 only at the top or only at the bottom is conceivable here as well. The arrangement of the electrodes 42 causes a primary deflection of the ring actuator 40 in a radial direction, i.e. parallel to the ring plane, the expansion and contraction of the ring actuator 40 in an axial direction being merely a second-order effect. In principle, the ratio of the extensions (ratio of change in radius and change in geometry along the axis of rotational symmetry) can be influenced by the choice of the electrode position in conjunction with the choice of the electrostrictive material, or the piezoelectric material. In a manner, it is thereby possible to influence the deformation effect at the optical effective surface and hence the wavefront influencing in the design.

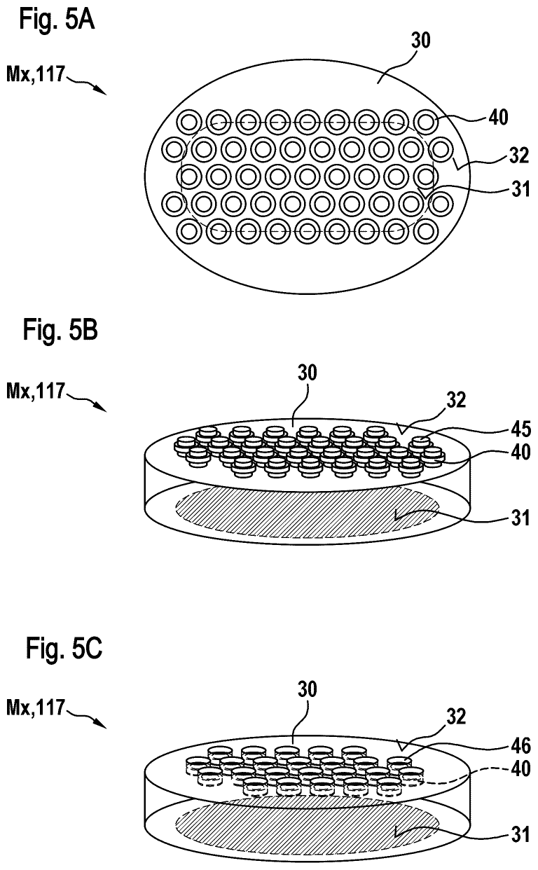

FIG. 5A shows a schematic view of a first embodiment of the disclosure, in which an optical element configured as a mirror Mx, 117 and such as can find application in one of the projection exposure apparatuses elucidated in FIG. 1 and FIG. 2, is illustrated. FIG. 5A shows the mirror Mx, 117, which comprises a main body 30 having an optical effective surface 31 and a rear side 32 opposite the latter, in a view from below, i.e. looking at the rear side 32 of the main body 30. The ring actuators 40 are arranged in a region corresponding to the optical effective surface 31, the arrangement of the ring actuators 40 going beyond the region of the optical effective surface 31 in order that a deformation with positive and negative gradients can be caused also in the edge region of the optical effective surface 31. This also involves expansion and contraction of the ring actuators 40 from a so-called zero position. This will be elucidated in detail in FIG. 14. In principle, the ring actuators 40 can also be provided only in the edge region or at other locations, provided that their actuation brings about a deformation of the optical effective surface 31.

FIG. 5B shows a further embodiment of the disclosure, in which an optical element configured as a mirror Mx, 117 is illustrated, which mirror, like the mirror Mx, 117 in FIG. 5B, comprises a main body 30 having an optical effective surface 31. The mirror Mx, 117 is again illustrated in a perspective rear view. Linking geometries configured as pins 45 for the ring actuators 40 are arranged on the rear side 32. The ring actuators 40, as will be elucidated in greater detail further below in FIG. 14, are mounted on the pins 45 by shrink fitting thereon, although some other connection technique, such as for example adhesive bonding or bonding, is also possible. Contraction or expansion of the ring actuator 40 leads to a constriction or an expansion of the pin 45, which in turn causes a deformation of the optical effective surface 31. The deformation effect can be compared with that of an actuator acting parallel to the surface, wherein in the case of the ring actuators 40 the axial component in the deflection contributes to the deformation, albeit only with a secondary contribution. The resultant deformation of the optical effective surface 31 can be used for correcting a thermal expansion of the main body 30 owing to absorption of electromagnetic radiation or else for correcting imaging aberrations generated elsewhere in a projection exposure apparatus 1, 101.

FIG. 5C shows a further embodiment of the disclosure, in which an optical element configured as a mirror Mx, 117 is illustrated, which mirror, like the mirror Mx, 117 in FIG. 5B, comprises a main body 30 having an optical effective surface 31. The mirror Mx, 117 is again illustrated in a rear perspective view. Linking geometries configured as cutouts 46 for the ring actuators 40 are arranged on the rear side 32. The ring actuators 40, as will be elucidated in greater detail further below in FIG. 14, are mounted in the cutout 46 by shrink fitting therein, although some other connection technique, such as for example adhesive bonding or bonding, is also possible. Contraction or expansion of the ring actuator 40 leads to a contraction or an expansion of the cutout 46, which in turn causes a deformation of the optical effective surface 31. The deformation effect can be compared with that of an actuator acting parallel to the surface, wherein in the case of the ring actuators 40 the axial component in the deflection can contribute to the deformation, albeit only with a secondary contribution. The resultant deformation of the optical effective surface 31 can be used for correcting a thermal expansion of the main body 30 owing to absorption of electromagnetic radiation or else for correcting imaging aberrations generated elsewhere in a projection exposure apparatus 1, 101.

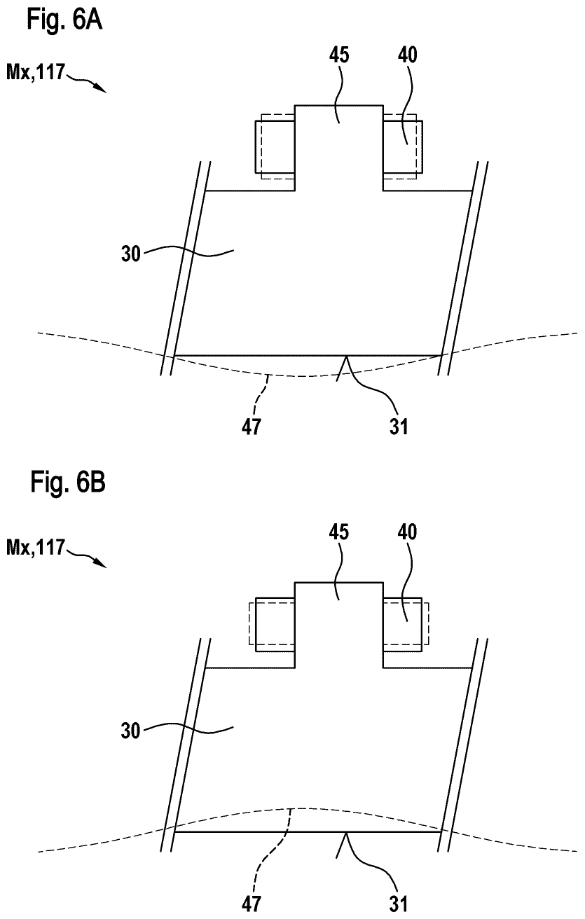

FIGS. 6A and 6B show a detail view of the disclosure illustrating a ring actuator 40 shrink-fitted on a pin 45 in two different operating states. Depending on the operating states of the ring actuator 40, the effect on the optical effective surface 31 of the main body 30 is illustrated.

FIG. 6A shows a ring actuator 40 in a contracted operating state, as a consequence of which the pin is constricted, which in turn causes a deformation 47 out of the optical effective surface 31.

FIG. 6B shows a ring actuator 40 in an expanded operating state, as a consequence of which a constriction of the pin 45 is expanded, which in turn causes a deformation 47 into the optical effective surface 31.

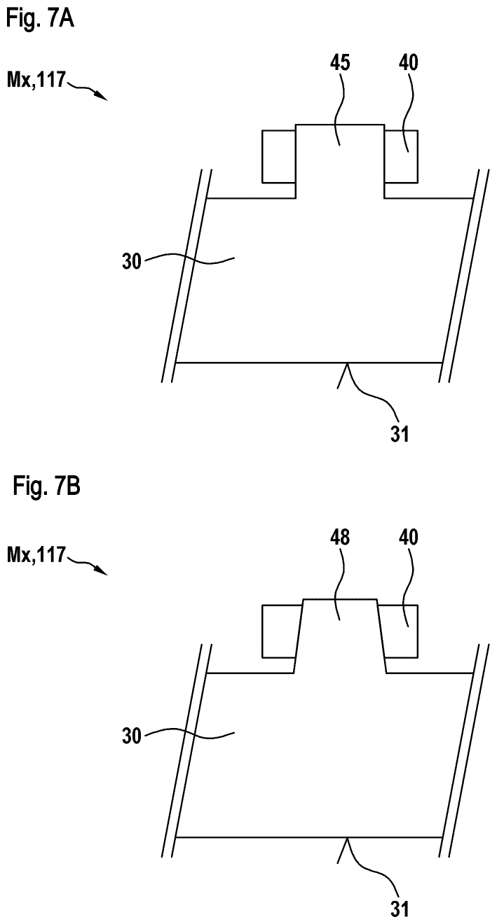

FIG. 7A shows a first embodiment of the pin 45, configured in a cylindrical fashion. This can allow for simple production and standard actuators to be used for the ring actuators 40 as well.

FIG. 7B shows a second embodiment of a pin 48, in the case of which the contact area with respect to the ring actuator is configured in a conical fashion. Fixing the ring actuator 40 can be effected at least partly by way of the ring actuator 40 being purely geometrically pushed forward onto the pin 48. As in the case of mounting onto cylindrical pins 45, the ring actuators 40 can likewise be configured in a hollow-cylindrical fashion, in which case the hollow-cylindrical internal shape of the ring actuator 40 adapts to the conical external geometry of the pin 48 during shrink-fitting thereon by way of a regional expansion of the internal diameter of the ring actuator 40. The resultant prestress of the pin 48 that varies over the axial expansion of the ring actuator 40 can be taken into account in the control. Alternatively, the internal geometry of the ring actuator 40 can likewise be configured in a manner corresponding to the pin 48, such that the contact area of the ring actuator 40 with respect to the pin 48 is configured in a conical fashion. Th is can allow for the compensation of diameter tolerances and the possibility of axial press-fitting.

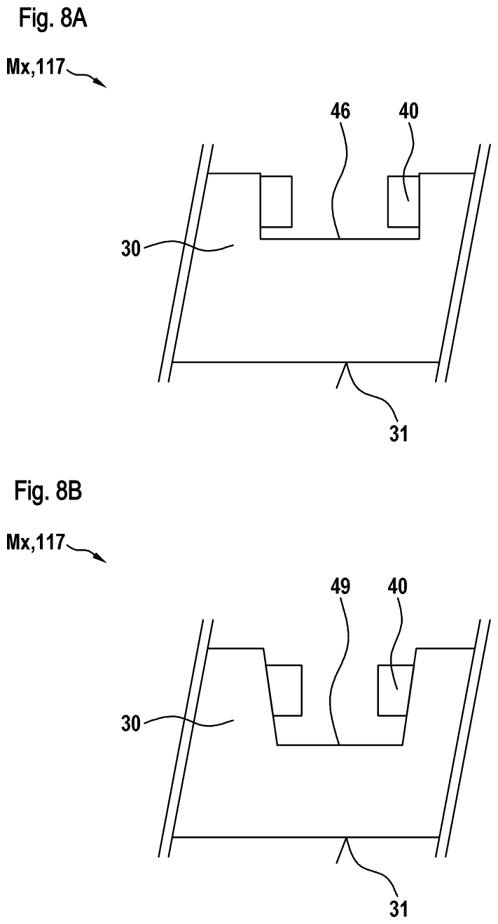

FIGS. 8A and 8B show a linking geometry configured as a cutout 46, 49, in one variant of the disclosure. What has been stated in regard to FIGS. 7A and 7B also applies, in principle, to the embodiment illustrated in FIGS. 8A and 8B, in which case the statements relate of course to the corresponding inner surfaces of the cutout and respectively to the outer surfaces of the ring actuator 40 and the ring actuator 40 is axially press-fitted or, using the thermal linear expansion, radially press-fitted or shrink-fitted in place.

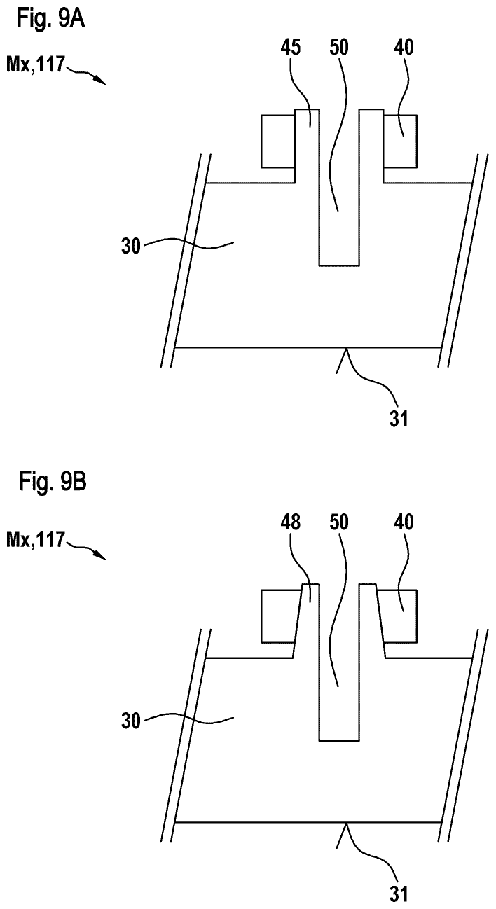

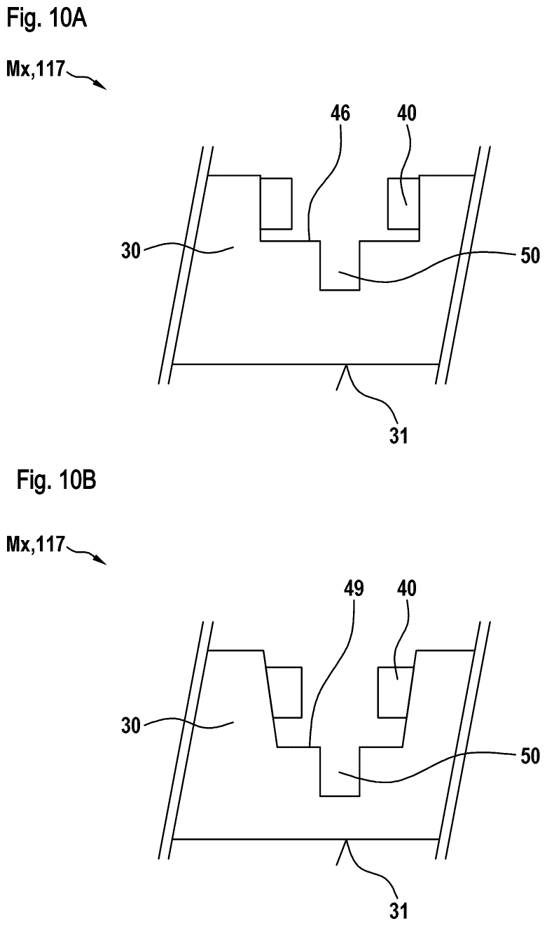

FIGS. 9A and 9B and FIGS. 10A and 10B show modifications of the disclosure for the linking geometries configured as pins 45, 48 and elucidated in FIGS. 7A and 7B, and the linking geometries configured as cutouts 46, 49 and elucidated in FIGS. 8A and 8B. This linking geometry comprises a mechanical transmission region comprising a recess 50, which region will be explained in detail below on the basis of the embodiment configured as a cylindrical pin 45 as illustrated in FIG. 9A. The recess 50 is formed centrally in the pin 45 and extends beyond the pin into the main body 30. Firstly, the recess 50 causes a reduction of the stiffness of the pin 45 and of the main body 30, whereby the deformation of the optical effective surface 31 can be suitably modified with the same deflection of the ring actuator 40. Secondly, the shape of the deformation on the optical effective surface 31 of the main body can also be adjusted, whereby this can be adjusted in virtually any desired way during production of the main body 30 and of the pins 45, 48, or respectively the cutouts 46, 49, by way of an additive method and the associated possibilities of a free geometric design. The effect of the recess 50 explained for FIG. 9A can be applied to the embodiments illustrated in FIGS. 9B, 10A and 10B.

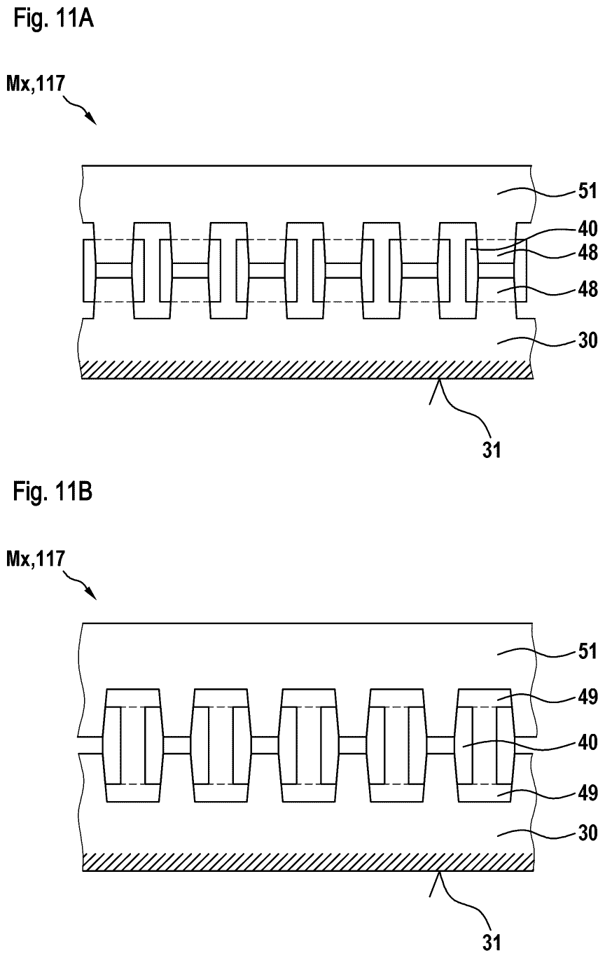

FIG. 11A shows a further embodiment of the disclosure, in which an optical element configured as a mirror Mx, 117 is illustrated. The latter, besides comprising the main body 30 having the optical effective surface 31, also comprises a supporting structure configured as a back plate 51, wherein the back plate 51 comprises conical pins 48 corresponding to the conical pins 48 configured in the main body 30. The ring actuators 40 are configured in the form of a sleeve, and so they can be connected both to the pins 48 of the back plate 51 and to the pins 48 of the main body 30. The back plate 51 acts as a supporting structure and either is connected to the main body 30 or to some other structure configured for absorbing forces or is supported on the main body 30 by way of the ring actuators 40. The supporting by way of the ring actuators 40 is possible by virtue of the fact that, for the deformation of the optical effective surface 31, the ring actuators 40 in the majority of cases are not all deflected in one direction and the non-deflected ring actuators 40 perform the support of the back plate 51. FIG. 11B shows a further embodiment of the disclosure, which, like the embodiment elucidated in FIG. 11A, comprises a supporting structure configured as a back plate 51. This differs merely in the linking geometry configured as a conical cutout 49. All further explanations match the elucidation given, and so reference is made to them.

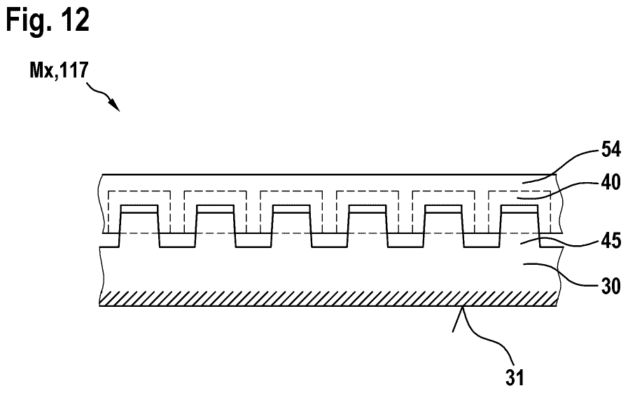

FIG. 12 shows a further embodiment of the disclosure, comprising a supporting structure with integrated ring actuators 40. In this case, a back plate 54 of the supporting structure is produced from actuator material 41, only the regions of the ring actuators 40 being formed with electrodes 42. The functioning is identical to that of the embodiment described in FIG. 11A.

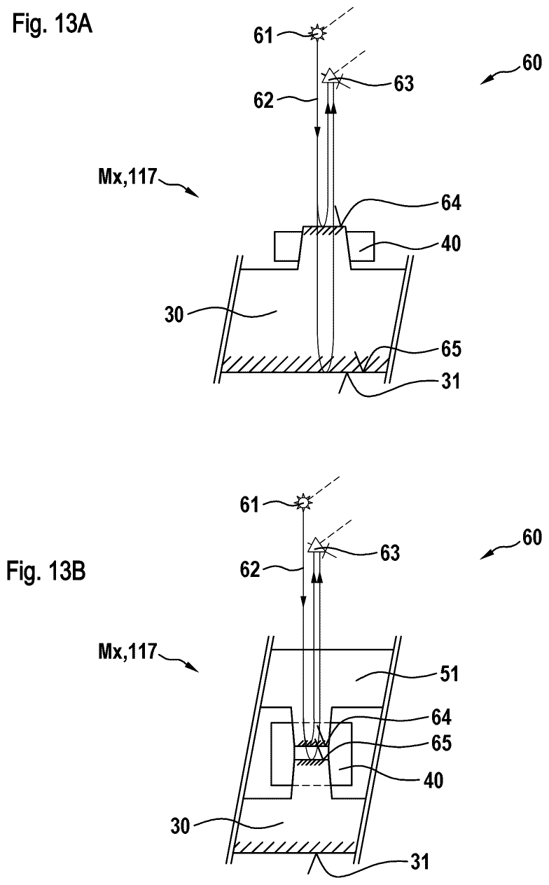

FIG. 13A shows a further embodiment of the disclosure, in which a detailed view of an optical element configured as a mirror Mx, 117 with a sensor 60 is illustrated. The mirror Mx, 117 comprises a main body 30 having an optical effective surface 31 and a ring actuator 40 shrink-fitted on a conical pin 48. The sensor 60 is configured in the manner of a Fabry-Perot interferometer in the embodiment illustrated in FIG. 13A. This interferometer comprises a light source 61, which emits a light beam 62 in the direction of the rear side of the main body 30, which light beam undergoes normal incidence on the rear side. The sensor 60 uses that end face of the pin 48 which is partly transmissive to the used wavelength of the light beam 62 as a first mirror surface 64 and the optical effective surface 31 as a second mirror surface 65, wherein a detector 63 detects the superimposition of the reflections from the first mirror surface 64 and the second mirror surface 65. From the phase difference between the detected light beams that is caused by a deformation of the main body, a change in the distance between the two mirror surfaces 64, 65 can be determined, from which the deformation of the optical effective surface 31 can then be determined. The sensor 60 in the center of the ring actuator 40 can mean that the deformation caused by the ring actuator 40 can be detected from the rear side of the main body 30 directly at the origination location. Accessibility is significantly better from the rear side of the main body 30 in comparison with a detection of the deformation from the optical effective surface 31.

FIG. 13B shows a further embodiment of the disclosure, in which a detailed view of an optical element configured as a mirror Mx, 117 with a sensor 60 is illustrated. The mirror Mx, 117 comprises a supporting structure 51 such as has been elucidated in FIG. 11A, and a sensor 60 likewise configured in the manner of a Fabry-Perot interferometer. In contrast to the arrangement elucidated in FIG. 13A, the sensor 60 uses the two end faces of the conical pins 48 formed at the back plate 51 and at the main body 30 as first mirror surface 64 and as second mirror surface 65. The deformation of the optical surface can be deduced with the aid of calibration data or model-based prediction, for example FEM.

FIG. 14 shows a diagram for elucidating a process of mounting a ring actuator into a linking geometry configured as a cutout. The external diameter of the ring actuator is indicated on the ordinate of the diagram, and the control voltage on the abscissa. In the embodiment shown, the ring actuator is controlled only with positive voltage and the diameter of the ring actuator decreases as the voltage rises. For mounting purposes, the ring actuator is controlled in a first voltage range S_{M} so that the diameter is definitely smaller than the tolerance-affected diameter range T_{A} of the cutout. The voltage range for control during operation S_{B} is below the voltage range S_{M} for mounting and below the voltage S_{G} at which the ring actuator has a diameter less than or equal to the largest diameter tolerance T_{A} of the cutout. The voltage range S_{B} for operation includes the so-called zero voltage S_{N}, corresponding to the voltage at which the optical effective surface has its predetermined surface shape. This can be achieved by the optical effective surface being reworked again after the mounting of the ring actuators, all the ring actuators being controlled with their zero voltage S_{N}. Alternatively, the deformation caused by the zero voltage S_{N} can also be kept during the production of the optical effective surface.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Main body
31 Optical effective surface
32 Rear side of the main body
40 Ring actuator
41 Actuator material
42 Electrodes
43 Line
44 Controller
45 Pin
46 Cutout
47 Deformation
48 Pin, conical
49 Cutout, conical
50 Recess
51 Back plate
54 Integrated back plate
60 Sensor
61 Light source
62 Laser beam
63 Detector
64 First mirror surface
65 Second mirror surface
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
M1-M6 Mirrors
S_{N} Voltage at zero point
S_{M} Voltage range for mounting
S_{B} Voltage range for operation
S_{G} Voltage at lower tolerance range of cutout
T_{A} Tolerance of cutout

1. An optical element, comprising:
a main body;
a first ring actuator connected to the main body; and
a second ring actuator connected to the main body, wherein:
the first and second ring actuators are configured to an optical effective surface of the optical element;
at least one of the first and second actuators is connected to the main body via a linking geometry; and
one of the following holds:
the linking geometry comprises a pin on the main body; or
the linking geometry comprises a cutout in the main body.

2. The optical element of claim 1, wherein the linking geometry comprise a pin on the main body.

3. The optical element of claim 2, wherein the main body and the pin are monolithic.

4. The optical element of claim 2, wherein the main body and the pin are integrally bonded to each other.

5. The optical element of claim 1, wherein the linking geometry comprises a cutout in the main body.

6. The optical element of claim 1, wherein a contact area of at least one of the first and second ring actuators is conical with respect to the linking geometry of the main body.

7. The optical element of claim 1, wherein a contact area of the linking geometry of the main body is conical with respect to at least one of the first and second ring actuators.

8. The optical element of claim 1, wherein at least one ring of the first and second ring actuators is connected to the linking geometry via shrink fitting thereon or shrink fitting therein.

9. The optical element of claim 1, wherein the linking geometry of at least one of the first and second ring actuators comprises a mechanical transmission region.

10. The optical element of claim 9, wherein the mechanical transmission region is configured to reduce a stiffness acting against a deflection of the ring actuator.

11. The optical element of claim 1, further comprising a supporting structure, wherein at least one of the first and second ring actuators is between the main body and the supporting structure.

12. The optical element of claim 11, wherein the supporting structure comprises a linking geometry corresponding to the at least one of the first and second ring actuators.

13. The optical element of claim 11, wherein the at least one of the first and second ring actuators is connected to a linking geometry configured as pins or cutouts in the main body and in the supporting structure.

14. The optical element of claim 11, wherein the at least one of the first and second ring actuators is integrated into the supporting structure.

15. The optical element of claim 1, wherein at least one of the first and second ring actuator comprises electrodes, and the electrodes comprise actuator material aligned radially in layers or axially in layers.

16. The optical element of claim 1, further comprising a sensor configured to determine a deformation of an optical effective surface of the optical element, wherein the sensor is configured to detect a signal which permits a correlation with the deformation of the optical effective surface.

17. The optical element of claim 16, wherein the optical element is configured so that an actuation direction of at least one of the first and second ring actuators is aligned normal to a contact area of the actuator with the optical element.

18. The optical element of claim 16, wherein the optical element is configured so that an actuation direction of at least one of the first and second ring actuators is aligned parallel to a contact area of the actuator with the optical element.

19. The optical element of claim 16, wherein the sensor is configured to detect the deformation of the optical effective surface through a center of at least one of the first and second ring actuators.

20. An apparatus, comprising:
an optical element according to claim 1,
wherein the apparatus is a semiconductor lithography projection exposure apparatus.

21. An optical element, comprising:
a sensor configured to determine a deformation of an optical effective surface of the optical element,
wherein the sensor is configured to detect a signal which permits a correlation with the deformation of the optical effective surface.

22.-27. (canceled)
